(19) United States
(12) Patent Application Publication
(10) Pub. No.: US 2013/0247818 A1
(43) Pub. Date: Sep. 26, 2013

(54) SILICA CRUCIBLE AND METHOD FOR FABRICATING THE SAME

(71) Applicants: Lu Wang, Shanghai (CN); Leilei Sun, Shanghai (CN); Laurent Molins, Carnot Nemours (FR); Paul Sargood, Carnot Nemours (FR)

(72) Inventors: Lu Wang, Shanghai (CN); Leilei Sun, Shanghai (CN); Laurent Molins, Carnot Nemours (FR); Paul Sargood, Carnot Nemours (FR)

(73) Assignee: SAINT-GOBAIN RESEARCH (SHANGHAI) CO., LTD., Shanghai (CN)

(21) Appl. No.: 13/861,965

(22) PCT Filed: May 25, 2011
(86) PCT No.: PCT/CN2011/074629

§ 371 Date: Apr. 12, 2013

(51) Int. Cl. C30B 15/10; F27B 14/10; C03B 5/43

(52) U.S. Cl. CPC C30B 15/10; C03B 5/43; F27B 14/10
USPC 117/208; 65/374.11; 427/230; 427/231; 427/237; 432/265

(57) ABSTRACT

A silica crucible and a fabricating method thereof are provided. The silica crucible includes a vitreous silica body having an inner surface and an outer surface, the inner surface of the vitreous silica body defining a cavity adapted for containing a molten material or a powder material; and a first coating layer formed on the inner surface of the vitreous silica body. The first coating layer is formed by pyrolysing a composite of aluminum, magnesium, calcium, titanium, zirconium, radium, chromium, selenium, barium, yttrium, cerium, hafnium, tantalum, tin or silicon under a predetermined temperature. The first coating layer substantially includes of a nonhomogeneous material, and an interface is defined by the homogeneous material and the nonhomogeneous material between the vitreous silica body and the coating layer. The first coating layer has strong adhesion capability and guarantees the coating layer will not be easily peeled off or removed.

### CROSS-REFERENCE TO RELATED APPLICATION(S)

The present application relates to and claims priority from International Patent Application No. PCT/CN2011/074629 filed May 25, 2011. The entire disclosure of the above-identified application is hereby incorporated by reference in its entirety.

### FIELD OF THE INVENTION

The present invention relates to a silica crucible designed to withstand high temperature and to prevent physical or chemical reaction with content material intended to be melted, transformed or decomposed, and particularly relates to a silica crucible with a coating with a strong adhesion and method for fabricating the same.

### BACKGROUND OF THE INVENTION

Silica crucibles are widely used for containing materials intended to be melted, decomposed, or in general, transformed, at high temperatures. The silica crucibles are designed to withstand high temperatures and have adequate mechanical and thermal properties. Most importantly, physical or chemical interaction between the materials contained in the silica crucibles and the inner surface of the silica crucibles should be prevented, which may pose the presence of certain impurities.

Typical application for the silica crucibles is for delicate preparations of precious metals or alloys, for example the preparation of superalloys. In order to avoid the presence of certain impurities, some methods for forming a coating on the inner wall of a silica crucible are disclosed by prior art, for example, in U.S. Pat. No. 4,723,764. A crucible made of pulverulent sintered molten silica is prepared by pouring a slip into a plaster mold, and then air-drying the slip. Next, an yttrium oxide powder-based coating is deposited inside the crucible, and the entire unit is then baked for two hours at 1200° C. However, the coating fails to provide a satisfactory solution to the problem of peeling off of the layer and to the diffusion of the constituents torn away.

The preparation of silicon single crystals grown by the Czochralsky process is one of the important applications for those silica crucibles. In a typical Czochralsky process, polycrystalline silicon (polysilicon) is charged to a crucible, the polysilicon is melted, a seed crystal is immersed into the molten silicon and a single crystal silicon ingot is grown by slow extraction.

The crucible of choice for use in the Czochralsky process is commonly referred to as a fused quartz crucible or simply a quartz crucible or so called silica crucible and is composed of an amorphous form of silica known as vitreous silica. One disadvantage associated with the use of vitreous silica, however, is the fact that during the Czochralsky pulling, molten silicon can react with silica crucible under high temperature 1450° C.-1540° C. and the low pressure inside Czochralsky furnace, to generate the SiO: SiO₂+Si→2SiO. The SiO will dissolve in molten silicon. Most of the SiO will vaporize and be taken away by high purity argon gas in the Czochralsky furnace. But some SiO will remain in silicon melt and finally grow into mono-crystalline silicon ingot. It will create dislocation defects to reduce greatly the ingot quality, such as, carrier lifetime and resistivity. Meanwhile, the crucible inner surface contacted with molten silicon will be devitrified to cristobalite phase. These devitrified spots will form separated devitrification spots or islands, and gradually grow to brownish rings and rosettes, and thus easily released into the molten silicon, and pollute the silicon melt and ingot as well.

Therefore, people developed some coating methods, which can generate a devitrification shell in the crucible inner surface to prevent defects described hereinabove. Detailed descriptions regarding surface-treated crucibles for improved zero dislocation performance are disclosed in U.S. Pat. No. 5,980,629. The crucible disclosed in U.S. Pat. No. 5,980,629 includes a body of vitreous silica having a bottom wall and a sidewall formation extending up from the bottom wall. A first devitrification promoter on the inner surface of the sidewall formation is distributed such that a first layer of substantially devitrified silica is formed on the inner surface of the crucible which is in contact with the molten semiconductor material when the molten semiconductor material is melted in the crucible during the crystal growing process. A second devitrification promoter on the outer surface of the sidewall formation distributed such that a second layer of substantially devitrified silica is formed on the outer surface of the crucible when the molten semiconductor material is melted in the crucible during the crystal growing process. The first substantially devitrified silica layer promotes uniform dissolution of the inner surface and significantly reduces the release of crystalline silica particulates into the molten semiconductor material as a crystal is pulled from the molten semiconductor material. The second substantially devitrified silica layer accordingly reinforces the vitreous silica body.

However, the adhering property of such barium hydroxide or barium carbonate coating layer disclosed in U.S. Pat. No. 5,980,629 is quite poor. It can be peeled off easily by external force, like, shock from vigorous transportation; besides, it can be easily scraped by finger or other contacting materials, for example, poly silicon raw materials during loading into crucible before the Czochralsky pulling. This phenomenon is widely noticed in all current barium hydroxide or barium carbonate coated crucibles using coating method from patents hereinabove.

Therefore, there is a need for silica crucibles that have more adhesive coating layers and would release fewer particulate contaminants into the molten materials or powder materials contained therein.

### SUMMARY OF THE INVENTION

To solve the problems described above, the present invention provide a silica crucible, including:

a vitreous silica body having an inner surface and an outer surface, the inner surface of the vitreous silica body defining a cavity adapted for containing a molten material or a powder material; and

a first coating layer formed on the inner surface of the vitreous silica body;

wherein the first coating layer is formed by pyrolysing a composite of aluminum, magnesium, calcium, titanium, zirconium, radium, chromium, selenium, barium, yttrium, cerium, hafnium, tantalum, tin and silicon under a predetermined temperature;

wherein the first coating layer is substantially consisted of a nonhomogeneous material, and an interface is defined by the homogeneous material and the nonhomogeneous material between the vitreous silica body and the coating layer.

Optionally, when forming the first coating layer, the predetermined temperature of the vitreous silica body is maintained between 650° C. and 1600° C.

Optionally, when forming the first coating layer, the predetermined temperature of the vitreous silica body is maintained between 750° C. and 1300° C.

Optionally, the vitreous silica body is made from quartz crystals, quartz sand or vitreous silica sand with particle size distribution (PSD) from 1 μm to 600 μm.

Optionally, the first coating layer includes a cristobalite crystalline content and the first coating layer is formed prior to containing the molten material or the powder material in the cavity of the silica crucible.

Optionally, the cristobalite crystalline content of the first coating layer is from 0.5 wt. % to 80 wt. % of the first coating layer.

Optionally, the cristobalite crystalline content of the first coating layer is from 1 wt. % to 50 wt. % of the first coating layer.

Optionally, the first coating layer is a continuous coating layer, and the continuous coating layer substantially covers the entirety of the inner surface of the vitreous silica body.

Optionally, the first coating layer is an uncontinuous coating layer and includes a plurality of voids exposing the inner surface of the vitreous silica body therefrom.

Optionally, the first coating layer is a single layer.

Optionally, the first coating layer is a stack of a plurality of sublayers, and the sublayers are sequentially formed on the inner surface of the vitreous silica body.

Optionally, the first coating layer includes a plurality of spot-shaped islands containing the crizstobalite crystalline content, and the spot-shaped islands are substantially randomly distributed over the entire extent of the first coating layer.

Optionally, the first coating layer includes a plurality of star-shaped islands containing the crizstobalite crystalline content, and the star-shaped islands are substantially randomly distributed over the entire extent of the first coating layer.

Optionally, the silica crucible further includes a second coating layer formed on the outer surface.

Optionally, the second coating layer is a slip coating.

Optionally, the second coating layer includes a cristobalite crystalline content and the second coating layer is formed prior to containing the molten material or the powder material in the cavity of the silica crucible.

Optionally, the cristobalite crystalline content of the second coating layer is from 0.5 wt. % to 80 wt. % of the second coating layer.

Optionally, the cristobalite crystalline content of the second coating layer is from 1 wt. % to 50 wt. % of the second coating layer.

Optionally, when forming the second coating layer, the predetermined temperature of the vitreous silica body is maintained between 650° C. and 1600° C.

Optionally, when forming the second coating layer, the predetermined temperature of the vitreous silica body is maintained between 750° C. and 1300° C.

Optionally, diameter of the silica crucible starts from 3 inches.

Optionally, the first coating layer has a thickness within a range from 0.05 μM to 10 μm.

Optionally, the second coating layer has a thickness within a range from 0.05 μm to 10 μm.

Optionally, the silica crucible is for preparation of crystals grown by Czochralsky process.

Optionally, the silica crucible is for preparation of poly crystals grown.

Optionally, the silica crucible is for melting superalloys.

Optionally, the silica crucible is for sintering and/or decomposing powders of electroluminescent substances, oxalates, alums, silicon nitride, alumina or zirconia.

Optionally, the silica crucible is for preparation of precious metals or alloys.

Optionally, the silica crucible is for preparation of special glasses.

The present invention further provides a method for manufacturing a silica crucible, including:

preparing a vitreous silica body having an inner surface and an outer surface, the inner surface of the vitreous silica body defining a cavity adapted for containing a molten material or a powder material;

heating the vitreous silica body to a temperature within a range from 650° C. to 1600° C.; and

distributing a first precursor onto the inner surface, wherein a first coating layer is formed on the inner surface by a chemical reaction between the first precursor and the vitreous silica body.

Optionally, the vitreous silica body is heated to a temperature within a range from 750° C. to 1300° C.

Optionally, during the step of distributing the first precursor onto the inner surface, the heated vitreous silica body is placed in an insulation hole.

Optionally, the first precursor is distributed by a distributor positioned inside the cavity, and the vitreous silica body rotates relative to the distributor.

Optionally, the insulation hole includes a container and the heated vitreous silica body is placed on the container.

Optionally, the container is driven to rotate relative to the distributor.

Optionally, the distributor is driven to rotate inside the cavity.

Optionally, during the step of distributing the first precursor onto the inner surface, a compressed gas carrying the first precursor is directed to a distributor and ejected from the distributor toward the inner surface of the heated vitreous silica body.

Optionally, pressure of the compressed gas is featured with a pressure within a range from 1 bar to 20 bar.

Optionally, the compressed gas is featured with a flow rate within a range from 5 m³/h to 1000 m³/h.

Optionally, the container rotates relative to the distributor with a rotation speed equal to or greater than 50 rpm.

Optionally, the first coating layer formed on the inner surface of the vitreous silica body includes a cristobalite crystalline content, and the cristobalite crystalline content of the first coating layer is from 0.5 wt. % to 80 wt. % of the first coating layer.

Optionally, the first coating layer formed on the inner surface of the vitreous silica body includes a cristobalite crystalline content, and the cristobalite crystalline content of the first coating layer is from 1 wt. % to 50 wt. % of the first coating layer.

Optionally, the first coating layer is a continuous coating layer and the continuous coating layer substantially covers the entirety of the inner surface of the vitreous silica body.

Optionally, the first coating layer is an uncontinuous coating layer and includes a plurality of voids exposing the inner surface of the vitreous silica body therefrom.

Optionally, the first coating layer is a single layer.

Optionally, the first coating layer is a stack of a plurality of sublayers, and the sublayers are sequentially formed on the inner surface of the vitreous silica body.

Optionally, the first coating layer includes a plurality of spot-shaped islands containing the crizstobalite crystalline content, and the spot-shaped islands are substantially randomly distributed over the entire extent of the first coating layer.

Optionally, the first coating layer includes a plurality of star-shaped islands containing the crizstobalite crystalline content, and the star-shaped islands are substantially randomly distributed over the entire extent of the first coating layer.

Optionally, the method for manufacturing a silica crucible further includes distributing a second precursor onto the outer surface of the vitreous silica body for forming a second coating layer on the outer surface.

Optionally, a chemical reaction occurs between the vitreous silica body and the second precursor at the outer surface, and the second coating layer formed on the outer surface includes a cristobalite crystalline content.

Optionally, the cristobalite crystalline content of the second coating layer is from 0.5 wt. % to 80 wt. % of the second coating layer.

Optionally, the cristobalite crystalline content of the second coating layer is from 1 wt. % to 50 wt. % of the second coating layer.

Optionally, diameter of the silica crucible starts from 3 inches.

Optionally, the first precursor includes a metal or metals selected from the group consisting of aluminum, magnesium, calcium, titanium, zirconium, radium, chromium, selenium, barium, yttrium, cerium, hafnium, tantalum, tin and silicon.

Optionally, the first precursor includes an organometallic based substance selected from the group consisting of chelate, alcoholate, acetate, acetylacetonate, and iso-propylate.

Optionally, the second precursor includes a metal or metals selected from the group consisting of aluminum, magnesium, calcium, titanium, zirconium, radium, chromium, selenium, barium, yttrium, cerium, hafnium, tantalum, tin and silicon.

Optionally, the second precursor includes an organometallic based substance selected from the group consisting of chelate, alcoholate, acetate, acetylacetonate, and iso-propylate.

Optionally, the second precursor is same as the first precursor.

Optionally, the second precursor is different from the first precursor.

Optionally, the first coating layer has a thickness within a range from 0.05 μm to 10 μm.

Optionally, the second coating layer has a thickness within a range from 0.05 μm to 10 μm.

Furthermore, the present invention provides a silica crucible, including:

a vitreous silica body having an inner surface and an outer surface, the inner surface of the vitreous silica body defining a cavity adapted for containing a molten material or a powder material; and

a first coating layer formed on the inner surface of the vitreous silica body, wherein the first coating layer includes a metal or metals selected from the group consisting of aluminum, magnesium, calcium, titanium, zirconium, radium, chromium, selenium, barium, yttrium, cerium, hafnium, tantalum, tin and silicon, and substantially does not contain hydroxid of earth alkali metals.

Optionally, the first coating layer further includes silica.

Optionally, the first coating layer includes at least two compounds selected from the group consisting of oxide, carbide, nitride, silicate and carbonate.

Furthermore, the present invention provides a silica crucible, including:

a vitreous silica body having an inner surface and an outer surface, the inner surface of the vitreous silica body defining a cavity adapted for containing a molten material or a powder material, wherein the vitreous silica body is substantially consisted of a homogeneous material; and

a coating layer formed on the inner surface of the vitreous silica body, wherein the coating layer is substantially consisted of a nonhomogeneous material, and an interface is defined by the homogeneous material and the nonhomogeneous material between the vitreous silica body and the coating layer;

wherein chemical composition of the nonhomogeneous material substantially gradually changes along a normal direction of the coating layer.

Optionally, the nonhomogeneous material includes a cristobalite crystalline content.

Optionally, when analyzing the chemical composition of the coating layer along the normal direction of the coating layer, intensity of the cristobalite crystalline content at a position relatively adjacent to the interface is greater than intensity of the cristobalite crystalline content at another position relatively apart from the interface.

Compared with the prior art, the present invention has the following advantages.

The coating layer formed on the inner surface or the outer surface of the vitreous silica body is not only a physical adhesion to the inner surface, but also with chemical bonds, which gives a strong adhesion capability and guarantees the coating layer will not be easily peeled off or removed through hand touching, raw materials loading into the silica crucible or vigorous transportation. Furthermore, the external coating layer enhances mechanical strength and extends lifetime of the silica crucible.

### BRIEF DESCRIPTION OF THE DRAWINGS

FIG. 1 is a schematic cross-sectional view illustrating a silica crucible according to a first embodiment of the present invention;

FIG. 2 is a schematic cross-sectional view illustrating a silica crucible according to a second embodiment of the present invention;

FIG. 3 is a top view of the silica crucible of FIG. 2;

FIG. 4 is a flow chart illustrating a method for manufacturing a silica crucible with strong coating in the first embodiment;

FIG. 5 shows a schematic view illustrating a system for coating a silica crucible according to an embodiment of the present invention;

FIG. 6 shows a coating layer photo under microscope ×5 according to a first embodiment of the present invention;

FIG. 7 shows a coating layer photo under microscope ×2000 according to the first embodiment of the present invention; and

FIG. 8 shows a coating layer photo under microscope ×5000 according to a second embodiment of the present invention.

### DESCRIPTION OF THE PREFERRED EMBODIMENTS

In order to solve the problems described above, the present invention provides a silica crucible and a method for manufacturing the silica crucible. The silica crucible includes: a vitreous silica body having an inner surface and an outer surface, the inner surface of the vitreous silica body defining a cavity adapted for containing a molten material or a powder material; and a first coating layer formed on the inner surface of the vitreous silica body. The vitreous silica body is made from quartz crystals, quartz sand or vitreous silica sand with particle size from 1 μm to 600 μm. The vitreous silica body could be flame fused, electrically fused or arc plasma fused. Possibly, the vitreous silica body could be manufactured with different layers in term of quality of quartz crystals, quartz sand or vitreous silica sand. The first coating layer is formed by pyrolysing a composite of aluminum, magnesium, calcium, titanium, zirconium, radium, chromium, selenium, barium, yttrium, cerium, hafnium, tantalum, tin and silicon under a predetermined temperature. The first coating layer includes a cristobalite crystalline content, and the first coating layer is formed prior to containing the molten material or the powder material in the cavity of the silica crucible. The silica crucible further includes a second coating layer possibly formed on the outer surface by distributing a second precursor onto the outer surface of the silica crucible under a predetermined temperature. Optionally, the second coating layer is a slip coating on the outer surface. The second coating layer may be formed at the same time with the first coating layer. Alternatively, the first coating layer and the second coating layer can also be separately formed in independent steps, respectively. The second precursor may be same as or different from the first precursor.

Hereunder, the present invention will be described in detail with reference to embodiments, in conjunction with the accompanying drawings.

Although the present invention has been disclosed hereinafter as above with reference to preferred embodiments in detail, the present invention can be implemented in other embodiments, which are different. Therefore, the present invention should not be limited to the embodiments disclosed here.

FIG. 1 is a schematic cross-sectional view illustrating a silica crucible, according to a first embodiment of the present invention. Referring to FIG. 1, a silica crucible 10 includes: a vitreous silica body 12 having an inner surface 14 and an outer surface 16, the inner surface 14 of the vitreous silica body defining a cavity adapted for containing a molten material or a powder material; and a first coating layer 18 formed on the inner surface 14 of the vitreous silica body 12. The vitreous silica body 12 is made from quartz crystals, quartz sand or vitreous silica sand with particle size distribution (PSD) from 1 μm to 600 μm. The first coating layer 18 (not to scale) covers the inner surface 14, forming a layer strongly adhering to the inner surface 14 which can be hardly removed by heavy external force or scrape. The first coating layer 18 is a microscopic non-homogeneous multi-component layer. The first coating layer 18 could include a cristobalite crystalline content, and the cristobalite crystalline content of the first coating layer 18 is from 0.5 wt. % to 80 wt. % of the first coating layer 18.

Optionally, the cristobalite crystalline content of the first coating layer 18 is from 1 wt. % to 50 wt. % of the first coating layer 18.

Optionally, diameter of the silica crucible starts from 3 inches.

The first coating layer 18 is formed prior to containing the molten material or the powder material in the cavity of the silica crucible. Specifically, the first coating layer 18 is formed by distributing a first precursor onto the inner surface 14 of the vitreous silica body 12 under a predetermined temperature. When forming the first coating layer, the predetermined temperature of the vitreous silica body is maintained between 650° C. and 1600° C. The first precursor includes a metal or metals selected from the group consisting of aluminum, magnesium, calcium, titanium, zirconium, radium, chromium, selenium, barium, yttrium, cerium, hafnium, tantalum, tin and silicon. The first precursor includes an organometallic based substance selected from the group consisting of chelate, alcoholate, acetate, acetylacetonate, and iso-propylate. The first precursor is carried by injecting a compressed gas. The hot silica crucible is rotating at a certain rotation speed such that the first precursor is sprayed onto the inner surface 14 of the silica crucible uniformly. The first precursor decomposes under the predetermined temperature and partially reacts with silica of the vitreous silica body 12 and forms a strong adhering coating layer on the inner surface 14. It generates at least two compounds selected from the group consisting of oxide, carbide, nitride, silicate and carbonate. The first coating layer is substantially consisted of a nonhomogeneous material, and an interface is defined by the homogeneous material and the nonhomogeneous material between the vitreous silica body and the coating layer. Therefore, the first coating layer 18 is not only a physical adhesion to the inner surface 14, but also with chemical bonds, which gives a strong adhesion capability and guarantees the first coating layer 18 will not easily peeled off or removed through hand touching, raw materials loading into the silica crucible or vigorous transportation. Furthermore, the first coating layer 18 releases fewer particulate contaminants while the silica crucible is containing melted materials.

Optionally, when forming the first coating layer, the predetermined temperature of the vitreous silica body is maintained between 750° C. and 1300° C.

Optionally, the first coating layer 18 is a continuous coating layer and substantially covers the entirety of the inner surface of the crucible body.

Optionally, the first coating layer 18 is an uncontinuous coating layer, and the first coating layer includes a plurality of voids exposing the inner surface of the crucible body therefrom.

Optionally, the first coating layer 18 is a stack of a plurality of sublayers, and the sublayers are sequentially formed on the inner surface of the crucible body.

Optionally, the first coating layer 18 includes a plurality of spot-shaped islands containing the crizstobalite crystalline content, and the spot-shaped are substantially randomly distributed over the entire extent of the first coating layer.

Optionally, the first coating layer 18 includes a plurality of star-shaped islands containing the crizstobalite crystalline content, and the star-shaped are substantially randomly distributed over the entire extent of the first coating layer.

Optionally, the first coating layer 18 has a thickness within a range from 0.05 μm to 10 μm.

Optionally, the silica crucible 10 is for the preparation of crystals grown by Czochralsky process.

Optionally, the silica crucible 10 is for preparation of poly crystals grown.

Optionally, the silica crucible 10 is for melting superalloys.

Optionally, the silica crucible 10 is for sintering and/or decomposing powders of electroluminescent substances, oxalates, alums, silicon nitride, alumina or zirconia.

Optionally, the silica crucible 10 is for preparation of precious metals or alloys.

Optionally, the silica crucible 10 is for preparation of special glasses, such as glasses for laser systems.

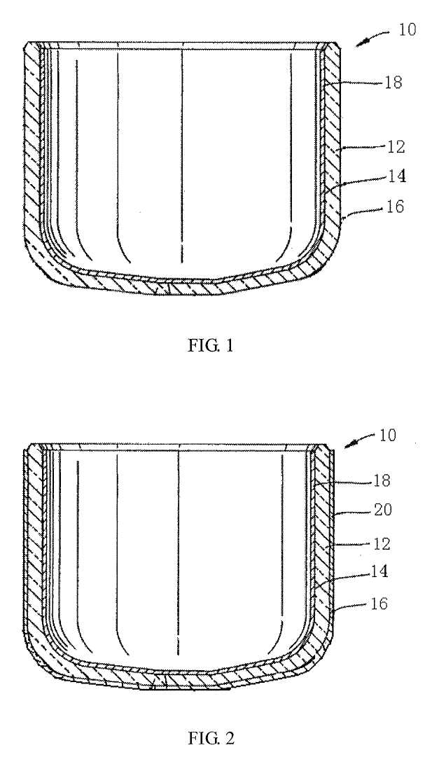

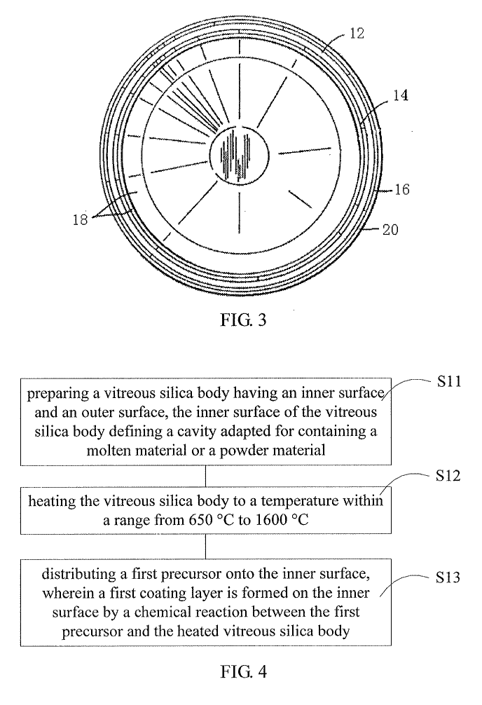

In an alternative embodiment illustrated in FIGS. 2 and 3, a silica crucible with an internal coating layer and an outer coating layer is provided. Referring to FIGS. 2 and 3, the silica crucible 10 includes: a vitreous silica body 12 having an inner surface 14 and an outer surface 16, the inner surface 14 of the vitreous silica body defining a cavity adapted for containing a molten material or a powder material; a first coating layer 18 formed on the inner surface 14 of the vitreous silica body 12; and a second coating layer 20 formed on the outer surface 16 of the vitreous silica body 12. The first coating layer 18 (not to scale) covers the inner surface 14, forming a layer strongly adhering to the inner surface 14 which can be hardly removed by heavy external force or scrape. The second coating layer 20 (not to scale) covers the outer surface 16, forming a layer strongly adhering to the outer surface 16 which can be hardly removed by heavy force or scrape. The second coating layer 20 includes a cristobalite crystalline content which is from 0.5 wt. % to 80 wt. % of the second coating layer 20.

Optionally, the cristobalite crystalline content of the second coating layer 20 is from 1 wt. % to 50 wt. % of the second coating layer.

Optionally, diameter of the silica crucible starts from 3 inches.

Similar to the first coating layer 18, the second coating layer 20 is formed prior to containing the molten material or the powder material in the cavity of the silica crucible. Specifically, the second coating layer 20 is formed by distributing a second precursor onto the outer surface 16 of the vitreous silica body 12 while temperature of the vitreous silica body 12 is maintained between 650° C. and 1600° C. The second precursor is carried by injecting a compressed gas. The hot silica crucible is rotating at a certain rotation speed such that the second precursor is sprayed onto the outer surface 16 of the silica crucible uniformly. Meanwhile, the second precursor decomposes under high temperature and partially reacts with silica of the vitreous silica body 12 and forms a strong coating layer on the outer surface 16. It generates at least two compounds selected from the group consisting of oxide, carbide, nitride, silicate and carbonate. Therefore, the second coating layer 20 is not only a physical adhesion to the outer surface 14, but also with chemical bonds, which gives a strong adhesion capability and guarantees the second coating layer 20 will not be easily peeled off or removed through hand touching, raw materials loading into the silica crucible or vigorous transportation. Furthermore, the second coating layer 20 enhances mechanical strength and extends the lifetime of the silica crucible.

In a specific embodiment, the second coating layer is a slip coating.

Optionally, when forming the second coating layer, the temperature of the vitreous silica body is maintained between 750° C. and 1300° C.

Optionally, the second coating layer 20 is a continuous coating layer and substantially covers the entirety of the outer surface of the crucible body.

Optionally, the second coating layer 20 is an uncontinuous coating layer, and the second coating layer includes a plurality of voids exposing the inner surface of the crucible body therefrom.

Optionally, the second coating layer 20 is a stack of a plurality of sublayers, and the sublayers are sequentially formed on the outer surface of the crucible body.

Optionally, the second coating layer 20 includes a plurality of spot-shaped islands containing the crizstobalite crystalline content, and the spot-shaped are substantially randomly distributed over the entire extent of the second coating layer.

Optionally, the second coating layer 20 includes a plurality of star-shaped islands containing the crizstobalite crystalline content, and the star-shaped islands are substantially randomly distributed over the entire extent of the second coating layer.

Optionally, the second coating layer 20 has a thickness within a range from 0.05 μm to 10 μm.

Optionally, the second precursor includes a metal or metals selected from the group consisting of aluminum, magnesium, calcium, titanium, zirconium, radium, chromium, selenium, barium, yttrium, cerium, hafnium, tantalum, tin and silicon.

Optionally, the second precursor includes comprises an organometallic based substance selected from the group consisting of chelate, alcoholate, acetate, acetylacetonate, and iso-propylate.

Optionally, the second precursor is same as the first precursor.

Optionally, the second precursor is different from the first precursor.

In another embodiment, the present invention provides a silica crucible, including: a vitreous silica body having an inner surface and an outer surface, the inner surface of the vitreous silica body defining a cavity adapted for containing a molten material or a powder material; and a first coating layer formed on the inner surface of the vitreous silica body, wherein the first coating layer includes a metal or metals selected from the group consisting of aluminum, magnesium, calcium, titanium, zirconium, radium, chromium, selenium, barium, yttrium, cerium, hafnium, tantalum, tin and silicon, and substantially does not contain hydroxid of earth alkali metals. Furthermore, the first coating layer further includes silica.

Optionally, the first coating layer includes at least two compounds selected from the group consisting of oxide, carbide, nitride, silicate and carbonate.

In one more embodiment, the present invention provides a silica crucible, including: a crucible body having an inner surface and an outer surface, the inner surface of the crucible body defining a cavity adapted for containing a molten material or powder material, wherein the crucible body is substantially consisted of a homogeneous material; and a coating layer formed on the inner surface of the crucible body, wherein the first coating layer is substantially consisted of a nonhomogeneous material, and an interface is defined by the homogeneous material and the nonhomogeneous material between the crucible body and the coating layer.

Specifically, chemical composition of the nonhomogeneous material substantially gradually changes along a normal direction of the coating layer. When analyzing the chemical composition of the coating layer along the normal direction of the coating layer, intensity of the cristobalite crystalline content relatively at a position adjacent to the interface is greater than intensity of the cristobalite crystalline content at another position relatively apart from the interface.

Specifically, the nonhomogeneous material includes a cristobalite crystalline content.

The present invention further provides a method for manufacturing a silica crucible. The silica crucible 10 includes: a vitreous silica body 12 having an inner surface 14 and an outer surface 16, the inner surface 14 of the vitreous silica body defining a cavity adapted for containing a molten material or a powder material; and a first coating layer 18 formed on the inner surface 14 of the vitreous silica body 12. FIG. 4 is a flow chart illustrating a method for manufacturing a silica crucible with strong coating in the first embodiment. The method includes:

Step S11: preparing a vitreous silica body having an inner surface and an outer surface, the inner surface of the vitreous silica body defining a cavity adapted for containing a molten material or a powder material;

Step S12: heating the vitreous silica body to a temperature within a range from 650° C. to 1600° C.; and

Step S13: distributing a first precursor onto the inner surface, wherein a first coating layer is formed on the inner surface by a chemical reaction between the first precursor and the vitreous silica body.

Optionally, the vitreous silica body is heated to a temperature within a range from 750° C. to 1300° C.

Optionally, diameter of the silica crucible used in the embodiment starts from 3 inches.

Optionally, the vitreous silica body is made from quartz crystals, quartz sand or vitreous silica sand with PSD from 1 μm to 600 μm.

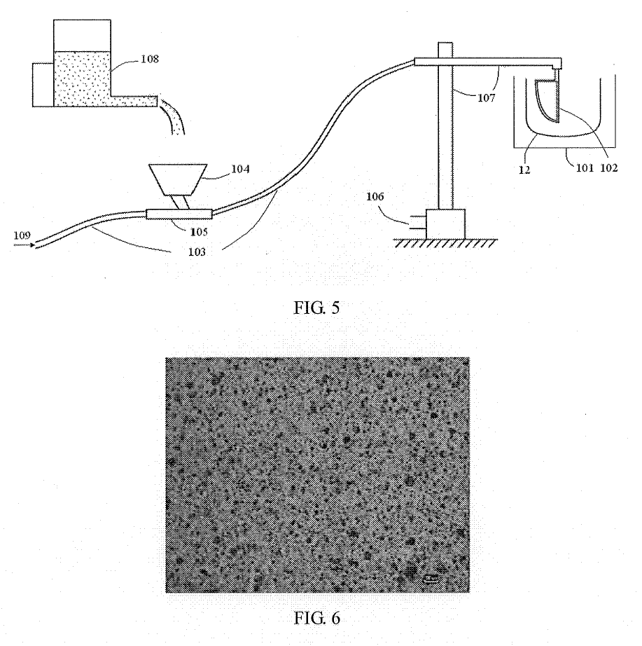

FIG. 5 shows a schematic view illustrating a system for coating a silica crucible according to an embodiment of the present invention. In one embodiment, a vitreous silica body 12 is provided. The heated vitreous silica body 12 is placed in an insulation hole during the process of distributing the first precursor onto the inner surface. The insulation hole includes a container 101. The heated vitreous silica body 12 is placed in the container 101, and the distributor is driven to rotate inside the cavity. In another embodiment, the first precursor is distributed by a distributor 102 positioned inside the cavity, and the vitreous silica body 12 rotates relative to the distributor 102. Optionally, the container 101 rotates above 50 rpm. During the process of distributing the first precursor onto the inner surface, a compressed gas 109 carrying the first precursor is directed to the distributor and ejected from the distributor 102 toward the inner surface of the heated vitreous silica body 12.

According to the embodiment, an auto feeder 108 is provided. The auto feeder includes a compressed gas pipe 103, a tundish 104 and a venture 105. The tundish 104 and the venturi 105 are connected with the compressed gas pipe 103 and are used for adding the precursor into the compressed gas pipe 103. The auto feeder 108 can feed the precursor continuously and control the feeding speed precisely. In the embodiment, a plurality of metallic arms 107 are fixed on the rotation container 101 and a plurality of distributors 102 are fixed on the metallic arms 107. The distributors 102 are designed to uniformly spray the precursor with the compressed gas 109 onto surface of the hot silica crucible inner surface 14. The metallic arms 107 hold the distributors 102 to move up and down, and rotate horizontally. The metallic arms 107 are driven by a driving system 106 in order to guarantee the fast movement of spray distributors to prevent the hot silica crucible 12 from cooling down. The driving system 106 is a motor or a pneumatic system. In the depositing process, the temperature of the vitreous silica body 12 is maintained between 650° C. and 1600° C.

In addition, there is a compressed gas system connected to the auto feeder 108 and the distributors 102 for transporting and spraying the precursor. Optionally, the compressed gas 109 has a pressure within a range from 1 bar to 20 bar; and the compressed gas 109 has a flow rate within a range from 5 m³/h to 1000 m³/h. The first precursor decomposes under high temperature and partially reacts with silica of the vitreous silica body 12 and forms a first coating layer 18 on the inner surface 14. It generates a mixture of composites which includes at least two compounds selected from the group consisting of oxide, carbide, nitride, silicate and carbonate. Therefore, the first coating layer 18 is not only a physical adhesion to the inner surface 14, but also with chemical bonds, which gives a strong adhesion capability and guarantees the first coating layer 18 will not be easily peeled off or removed through hand touching, raw materials loading into the silica crucible or vigorous transportation. Furthermore, the first coating layer 18 releases fewer particulate contaminants while the silica crucible is containing melted materials.

Optionally, during the depositing process, the temperature of the vitreous silica body 12 is maintained between 750° C. and 1300° C.

Optionally, the first coating layer formed on the inner surface of the vitreous silica body includes a cristobalite crystalline content which is from 0.5 wt. % to 80 wt. % of the first coating layer.

Optionally, the cristobalite crystalline content of the first coating layer is from 1 wt. % to 50 wt. % of the first coating layer.

The first precursor includes a metal or metals selected from the group consisting of aluminum, magnesium, calcium, titanium, zirconium, radium, chromium, selenium, barium, yttrium, cerium, hafnium, tantalum, tin and silicon. The first precursor comprises an organometallic based substance selected from the group consisting of chelate, alcoholate, acetate, acetylacetonate, and iso-propylate. In one embodiment, calcium acetate is used in the embodiment. Calcium acetate decomposes to calcium oxide and calcium carbonate, and side products, such as, water, and carbon dioxide, under high temperature. The decomposed calcium oxide and calcium carbonate react with silica and form a strong and uniform coating layer on the inner surface 14 of the vitreous silica body 12. Optionally, the first coating layer has a thickness within a range from 0.05 μm to 10 μm.

In another embodiment, barium isopropylate is used as the first precursor. Barium isopropylate decomposes to barium oxide and barium carbonate under high temperature. The decomposed barium oxide and barium carbonate react with silica and forms a strong and uniform coating layer on the inner surface 14 of the vitreous silica body 12.

In another embodiment, aluminium acetylacetonate is used as the precursor. Aluminium acetylacetonate decomposes to aluminium oxide under high temperature. The decomposed aluminium oxide reacts with silica and forms a strong and uniform coating layer on the inner surface 14 of the vitreous silica body 12.

In another embodiment, yttrium acetylacetonate is used as the first precursor. Yttrium acetylacetonate decomposes to yttrium oxide under high temperature. The decomposed yttrium oxide reacts with silica and forms a strong and uniform coating layer on the inner surface 14 of the vitreous silica body 12.

In another embodiment, hafnium acetylacetonate is used as the first precursor. Hafnium acetylacetonate precursor is carried by compressed gas with ammonia. Hafnium decomposes and reacts with ammonia to generate hafnium nitride under high temperature. The hafnium nitride forms a strong and uniform coating layer on the silica crucible inner surface 14 of the vitreous silica body 12.

Furthermore, the present invention provides a method for manufacturing a silica crucible with a first coating layer on the inner surface and a second coating layer on the outer surface of the vitreous silica body. Referring to FIG. 2, a schematic cross-sectional view illustrating an internally and externally treated silica crucible of the present invention is provided. Specifically, the silica crucible 10 manufactured in the embodiment include: a vitreous silica body 12 having an inner surface 14 and an outer surface 16, the inner surface 14 of the vitreous silica body defining a cavity adapted for containing a molten material or a powder material; a first coating layer 18 formed on the inner surface 14 of the vitreous silica body 12; and a second coating layer 20 formed on the outer surface 16 of the vitreous silica body 12. The first coating layer 18 (not to scale) covers the inner surface 14, forming a layer strongly adhering to the inner surface 14 which can be hardly removed by heavy force or scrape. The second coating layer 20 (not to scale) covers the outer surface 16, forming a layer strongly adhering to the outer surface 16 which can be hardly removed by heavy external force or scrape.

Optionally, diameter of the silica crucible used in the embodiment is equal to or above 3 inches.

Specifically, a second precursor is deposited onto the outer surface 16 of the hot vitreous silica body 12 whose temperature is maintained between 650° C. and 1600° C. The second precursor is carried into an insulation hole of a rotation bench container by injecting a compressed gas into the insulation hole. The second precursor decomposes under high temperature and partially reacts with silica of the vitreous silica body 12 and forms a second coating layer 20 on the outer surface 16. It generates at least two compounds selected from the group consisting of oxide, carbide, nitride, silicate and carbonate. The second coating layer formed on the outer surface includes a cristobalite crystalline content which is from 0.5 wt. % to 80 wt. % of the second coating layer 18. Therefore, the second coating layer 20 is not only a physical adhesion to the inner surface 14, but also with chemical bonds, which gives a strong adhesion capability and guarantees the second coating layer 20 will not be easily peeled off or removed through hand touching, raw materials loading into the silica crucible or vigorous transportation. Furthermore, the second coating layer 20 enhances mechanical strength and extends life of the silica crucible.

Optionally, when forming the second coating layer, the temperature of the vitreous silica body 12 is maintained between 750° C. and 1300° C.

Optionally, the cristobalite crystalline content of the second coating layer 20 is from 1 wt. % to 50 wt. % of the second coating, layer 18.

Optionally, the second precursor is same as the first precursor.

Optionally, the second precursor is different from the first precursor.

Optionally, the second coating layer 20 is formed at the same time with the first coating layer 18.

Optionally, the first coating layer 18 and the second coating layer 20 are separately formed in independent steps.

Optionally, the second coating layer includes a cristobalite crystalline content and the second coating layer is formed prior to containing the molten material or the powder material in the cavity of the silica crucible.

Optionally, the second precursor includes a metal or metals selected from the group consisting of aluminum, magnesium, calcium, titanium, zirconium, radium, chromium, selenium, barium, yttrium, cerium, hafnium, tantalum, tin and silicon.

Optionally, the second precursor includes an organometallic based substance selected from the group consisting of chelate, alcoholate, acetate, acetylacetonate, and iso-propylate.

Optionally, the second coating layer 20 has a thickness within a range from 0.05 μm to 10 μm.

In a specific embodiment, the second coating layer is a slip coating. And the slip coating is formed by the following steps.

Prepare aqueous slurry of barium oxide. Mix the high purity barium oxide powder of metallic impurity less than 1 wt. % with deionized water. The aqueous slurry of the barium oxide has a concentration within a range from 5 wt. % to 60 wt. %. Optionally, dispersant, such as methacrylic acid or methyl cellulose may be added in the aqueous slurry of the barium oxide to reduce the sedimentation. The aqueous slurry of the barium oxide is well mixed and aged. Then spray the aqueous slurry of the barium oxide onto the outer surface of the silica crucible. Specifically, the aqueous slurry of the barium oxide is placed in a sprayer container. The sprayer is connected to a pump to produce compressed gas. The aqueous slurry of the barium oxide is sprayed out with the compressed gas onto the outer surface of the silica crucible. The aqueous slurry of the barium oxide also can be brushed by clean brushes onto the outer surface of the silica crucible. Optionally, during the spraying process, the silica crucible has a temperature within a range from 20° C. to 300° C. After the spraying or brushing process, the silica crucible is placed in a drying oven with temperature from 80° C. to 300° C. in order to vaporize the water and dry the coating.

FIG. 6 shows a coating layer photo under microscope ×5 according to a first embodiment of the present invention.

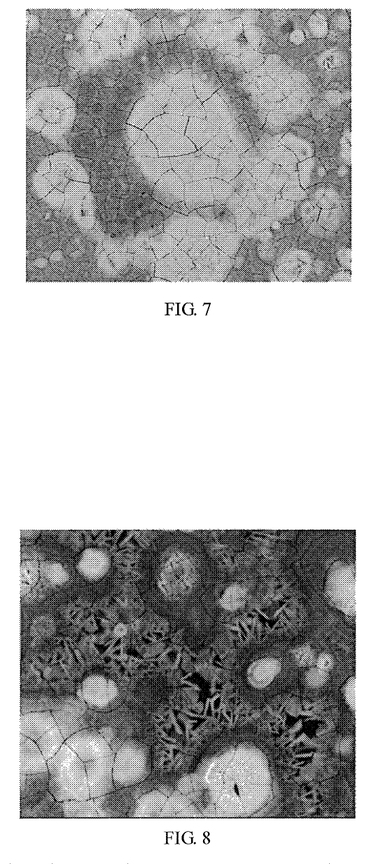

FIG. 7 shows a coating layer photo under microscope ×2000 according to the first embodiment of the present invention. The coating layer is a continuous coating layer and covers the inner surface of the silica crucible completely. The coating layer reacts with the vitreous silica body and generates a mixture of composites which includes at least two compounds selected from the group consisting of oxide, carbide, nitride, silicate and carbonate. After the vitreous silica body with the coating layer is cooled down, microcracks (as shown in FIG. 7) may be formed. However, the coating layer is not only a physical adhesion to the inner surface, but also with chemical bonds, which gives a strong adhesion capability and guarantees the coating layer will not be easily peeled off or removed through hand touching, raw materials loading into the silica crucible or vigorous transportation.

FIG. 8 shows a coating layer photo under microscope ×5000 according to a second embodiment of the present invention. The coating layer is an uncontinuous coating layer and doesn't cover the inner surface of the silica crucible completely. The coating layer reacts with silica of the vitreous silica body and generates a dendritic crystal structure at the interface edge.

In conclusion, according to the present invention, the coating layer formed on the inner surface or the outer surface of the vitreous silica body is not only a physical adhesion to the inner surface, but also with chemical bonds, which gives a strong adhesion capability and guarantees the coating layer will not be easily peeled off or removed through hand touching, raw materials loading into the silica crucible or vigorous transportation. Furthermore, the external coating layer enhances mechanical strength and extends lifetime of the silica crucible.

Although the present invention has been disclosed as above with reference to preferred embodiments thereof but will not be limited thereto. Those skilled in the art can modify and vary the embodiments without departing from the spirit and scope of the present invention. Accordingly, the scope of the present invention shall be defined in the appended claims.

1. A silica crucible, comprising:
a vitreous silica body having an inner surface and an outer surface, the inner surface of the vitreous silica body defining a cavity adapted for containing at least one of a molten material or a powder material; and
a first coating layer formed on the inner surface of the vitreous silica body;
wherein the first coating layer is formed by pyrolysing a composite of at least one of aluminum, magnesium, calcium, titanium, zirconium, radium, chromium, selenium, barium, yttrium, cerium, hafnium, tantalum, tin or silicon under a predetermined temperature; and
wherein the first coating layer substantially comprises a nonhomogeneous material, and an interface is defined by a homogeneous material and the nonhomogeneous material between the vitreous silica body and the coating layer.

2. The silica crucible of claim 1, wherein when forming the first coating layer, the predetermined temperature of the vitreous silica body is maintained between about 650° C. and about 1600° C.

3. The silica crucible of claim 1, wherein when forming the first coating layer, the predetermined temperature of the vitreous silica body is maintained between about 750° C. and about 1300° C.

4. The silica crucible of claim 1, wherein the vitreous silica body is made from at least one of quartz crystals, quartz sand or vitreous silica sand with particle size distribution from about 1 μm to about 600 μm.

5. The silica crucible of claim 1, wherein the first coating layer comprises a cristobalite crystalline content and the first coating layer is formed prior to containing at least one of the molten material or the powder material in the cavity of the silica crucible.

6. The silica crucible of claim 5, wherein the cristobalite crystalline content of the first coating layer is from about 0.5 wt. % to 80 wt. % of the first coating layer.

7. The silica crucible of claim 5, wherein the cristobalite crystalline content of the first coating layer is from about 1 wt. % to about 50 wt. % of the first coating layer.

8. The silica crucible of claim 1, wherein the first coating layer is a continuous coating layer, and the continuous coating layer substantially covers an entirety of the inner surface of the vitreous silica body.

9. The silica crucible of claim 1, wherein the first coating layer is a non-continuous coating layer and comprises a plurality of voids exposing the inner surface of the vitreous silica body therefrom.

10. The silica crucible of claim 1, wherein the first coating layer is a single layer.

11. The silica crucible of claim 1, wherein the first coating layer comprises a stack of a plurality of sublayers, and the sublayers are sequentially formed on the inner surface of the vitreous silica body.

12. The silica crucible of claim 1, wherein the first coating layer comprises a plurality of spot-shaped islands containing a crizstobalite crystalline content, and the spot-shaped islands are substantially randomly distributed over an entirety of the first coating layer.

13. The silica crucible of claim 1, wherein the first coating layer comprises a plurality of star-shaped islands containing crizstobalite crystalline content, and the star-shaped islands are substantially randomly distributed over an entirety of the first coating layer.

14. The silica crucible of claim 1, further comprising a second coating layer formed on the outer surface.

15. The silica crucible of claim 14, wherein the second coating layer is a slip coating.

16. The silica crucible of claim 14, wherein the second coating layer comprises a cristobalite crystalline content and the second coating layer is formed prior to containing at least one of the molten material or the powder material in the cavity of the silica crucible.

17. The silica crucible of claim 16, wherein the cristobalite crystalline content of the second coating layer is from about 0.5 wt. % to about 80 wt. % of the second coating layer.

18. The silica crucible of claim 16, wherein the cristobalite crystalline content of the second coating layer is from about 1 wt. % to about 50 wt. % of the second coating layer.

19. The silica crucible of claim 14, wherein when forming the second coating layer, the predetermined temperature of the vitreous silica body is maintained between about 650° C. and about 1600° C.

20. The silica crucible of claim 14, wherein when forming the second coating layer, the predetermined temperature of the vitreous silica body is maintained between about 750° C. and 1300° C.

21. The silica crucible of claim 1, wherein a diameter of the silica crucible is equal to or greater than 3 inches.

22. The silica crucible of claim 1, wherein the first coating layer has a thickness within a range from about 0.05 μm to about 10 μm.

23. The silica crucible of claim 14, wherein the second coating layer has a thickness within a range from about 0.05 μm to about 10 μm.

24. The silica crucible of claim 1, wherein the silica crucible is adapted for preparation of crystals grown by a Czochralsky process.

25. The silica crucible of claim 1, wherein the silica crucible is adapted for preparation of poly crystals grown.

26. The silica crucible of claim 1, wherein the silica crucible is adapted for melting superalloys.

27. The silica crucible of claim 1, wherein the silica crucible is adapted for sintering and/or decomposing powders of at least one of electroluminescent substances, oxalates, alums, silicon nitride, alumina or zirconia.

28. The silica crucible of claim 1, wherein the silica crucible is adapted for preparation of at least one of precious metals or alloys.

29. The silica crucible of claim 1, wherein the silica crucible is adapted for preparation of special glasses.

30. A method for manufacturing a silica crucible, comprising:
preparing a vitreous silica body having an inner surface and an outer surface, the inner surface of the vitreous silica body defining a cavity adapted for containing at least one of a molten material or a powder material;
heating the vitreous silica body to a temperature within a range of about 650° C. to about 1600° C.; and
distributing a first precursor onto the inner surface,
wherein a first coating layer is formed on the inner surface by a chemical reaction between the first precursor and the heated vitreous silica body.

31. The method for manufacturing a silica crucible of claim 30, wherein during the step of heating the vitreous silica body, the vitreous silica body is heated to a temperature within a range from about 750° C. to 1300° C.

32. The method for manufacturing a silica crucible of claim 30, wherein during the step of distributing the first precursor onto the inner surface, the heated vitreous silica body is placed in an insulation hole.

33. The method for manufacturing a silica crucible of claim 30, wherein the first precursor is distributed by a distributor positioned inside the cavity, and the vitreous silica body rotates relative to the distributor.

34. The method for manufacturing a silica crucible of claim 32, wherein the insulation hole comprises a container and the heated vitreous silica body is placed on the container.

35. The method for manufacturing a silica crucible of claim 34, wherein the container is driven to rotate relative to the distributor.

36. The method for manufacturing a silica crucible of claim 33, wherein the distributor is driven to rotate inside the cavity.

37. The method for manufacturing a silica crucible of claim 30, wherein during the step of distributing the first precursor onto the inner surface, a compressed gas carrying the first precursor is directed to a distributor and ejected from the distributor toward the inner surface of the heated vitreous silica body.

38. The method for manufacturing a silica crucible of claim 37, wherein pressure of the compressed gas is within a range from about 1 bar to about 20 bar.

39. The method for manufacturing a silica crucible of claim 37, wherein the compressed gas has a flow rate within a range from about 5 m³/h to about 1000 m³/h.

40. The method for manufacturing a silica crucible of claim 35, wherein the container rotates relative to the distributor with a rotation speed equal to or greater than 50 rpm.

41. The method for manufacturing a silica crucible of claim 30, wherein the first coating layer formed on the inner surface of the vitreous silica body comprises a cristobalite crystalline content, and the cristobalite crystalline content of the first coating layer is from about 0.5 wt. % to about 80 wt. % of the first coating layer.

42. The method for manufacturing a silica crucible of claim 30, wherein the first coating layer formed on the inner surface of the vitreous silica body comprises a cristobalite crystalline content, and the cristobalite crystalline content of the first coating layer is from about 1 wt. % to about 50 wt. % of the first coating layer.

43. The method for manufacturing a silica crucible of claim 30, wherein the first coating layer is a continuous coating layer and the continuous coating layer substantially covers an entirety of the inner surface of the vitreous silica body.

44. The method for manufacturing a silica crucible of claim 30, wherein the first coating layer is a non-continuous coating layer and comprises a plurality of voids exposing the inner surface of the vitreous silica body therefrom.

45. The method for manufacturing a silica crucible of claim 30, wherein the first coating layer is a single layer.

46. The method for manufacturing a silica crucible of claim 30, wherein the first coating layer is a stack of a plurality of sublayers, and the sublayers are sequentially formed on the inner surface of the vitreous silica body.

47. The method for manufacturing a silica crucible of claim 30, wherein the first coating layer comprises a plurality of spot-shaped islands containing a crizstobalite crystalline content, and the spot-shaped islands are substantially randomly distributed over an entirety of the first coating layer.

48. The method for manufacturing a silica crucible of claim 30, wherein the first coating layer comprises a plurality of star-shaped islands containing a crizstobalite crystalline content, and the star-shaped islands are substantially randomly distributed over an entirety of the first coating layer.

49. The method for manufacturing a silica crucible of claim 30, further comprising distributing a second precursor onto the outer surface of the vitreous silica body for forming a second coating layer on the outer surface.

50. The method for manufacturing a silica crucible of claim 49, wherein a chemical reaction occurs between the vitreous silica body and the second precursor at the outer surface, and the second coating layer formed on the outer surface comprises a cristobalite crystalline content.

51. The method for manufacturing a silica crucible of claim 50, wherein the cristobalite crystalline content of the second coating layer is from about 0.5 wt. % to about 80 wt. % of the second coating layer.

52. The method for manufacturing a silica crucible of claim 50, wherein the cristobalite crystalline content of the second coating layer is from about 1 wt. % to about 50 wt. % of the second coating layer.

53. The method for manufacturing a silica crucible of claim 30, wherein the silica crucible has a diameter equal to or greater than from 3 inches.

54. The method for manufacturing a silica crucible of claim 30, wherein the first precursor comprises at least one of a metal or metals, the metal or metals comprising at least one of aluminum, magnesium, calcium, titanium, zirconium, radium, chromium, selenium, barium, yttrium, cerium, hafnium, tantalum, tin and silicon.

55. The method for manufacturing a silica crucible of claim 30, wherein the first precursor comprises an organometallic based substance, the organometallic substance comprising at least one of chelate, alcoholate, acetate, acetylacetonate, and iso-propylate.

56. The method for manufacturing a silica crucible of claim 49, wherein the second precursor comprises at least one of a metal or metals, the metal or metals comprising at least one of aluminum, magnesium, calcium, titanium, zirconium, radium, chromium, selenium, barium, yttrium, cerium, hafnium, tantalum, tin and silicon.

57. The method for manufacturing a silica crucible of claim 49, wherein the second precursor comprises an organometallic based substance, the organometallic substance comprising at least one of chelate, alcoholate, acetate, acetylacetonate, or iso-propylate.

58. The method for manufacturing a silica crucible of claim 49, wherein the second precursor is similar to or same as the first precursor.

59. The method for manufacturing a silica crucible of claim 49, wherein the second precursor is different from the first precursor.

60. The method for manufacturing a silica crucible of claim 30, wherein the first coating layer has a thickness within a range from about 0.05 μm to about 10 μm.

61. The method for manufacturing a silica crucible of claim 49, wherein the second coating layer has a thickness within a range from about 0.05 μm to about 10 μm.

62. A silica crucible, comprising:
a vitreous silica body having an inner surface and an outer surface, the inner surface of the vitreous silica body defining a cavity adapted for containing at least one of a molten material or a powder material; and
a first coating layer formed on the inner surface of the vitreous silica body, wherein the first coating layer comprises at least one of a metal or metals, the metal or metals comprising at least one of aluminum, magnesium, calcium, titanium, zirconium, radium, chromium, selenium, barium, yttrium, cerium, hafnium, tantalum, tin or silicon, and substantially does not contain hydroxid of earth alkali metals.

63. The silica crucible of claim 62, wherein the first coating layer further comprises silica.

64. The silica crucible of claim 62, wherein the first coating layer comprises at least two compounds, the compounds comprising at least two of oxide, carbide, nitride, silicate or carbonate.

65. A silica crucible, comprising:
a vitreous silica body having an inner surface and an outer surface, the inner surface of the vitreous silica body defining a cavity adapted for containing at least one of a molten material or a powder material, wherein the vitreous silica body substantially comprises a homogeneous material; and
a coating layer formed on the inner surface of the vitreous silica body, wherein the coating layer substantially comprises of a nonhomogeneous material, and an interface is defined by a homogeneous material and the nonhomogeneous material between the vitreous silica body and the coating layer;
wherein a chemical composition of the nonhomogeneous material substantially gradually changes along a normal direction of the coating layer.

66. The silica crucible of claim 65, wherein the nonhomogeneous material comprises a cristobalite crystalline content.

67. The silica crucible of claim 66, wherein when analyzing the chemical composition of the coating layer along the normal direction of the coating layer, an intensity of the cristobalite crystalline content at a position relatively adjacent to the interface is greater than an intensity of the cristobalite crystalline content at another position relatively apart from the interface.
